(19) United States
(12) Patent Application Publication
(10) Pub. No.: US 2019/0229006 A1
(43) Pub. Date: Jul. 25, 2019

(54) SEMICONDUCTOR MANUFACTURING APPARATUS AND FILM FORMATION METHOD FOR A SEMICONDUCTOR DEVICE

(71) Applicant: ABLIC Inc., Chiba-shi (JP)

(72) Inventor: Hiroaki TADA, Chiba-shi (JP)

(21) Appl. No.: 16/225,849

(22) Filed: Dec. 19, 2018

(30) Foreign Application Priority Data
Jan. 25, 2018 (JP) 2018-010248

(51) Int. Cl. H01L 21/687; C23C 14/50; H01L 21/673

(52) U.S. Cl. CPC H01L 21/68728; H01L 21/67373; C23C 14/50

(57) ABSTRACT

Provided is an apparatus for manufacturing a semiconductor device capable of easily separating a substrate and a clamp. After a deposited film (101) is formed on a substrate (100) while a front surface outer-peripheral-portion of the substrate (100) is pressed with a main clamp (23a) and a sub-clamp (23b), the main clamp (23a) and the substrate (100) are separated from each other through use of a contraction force of the spring member (25) which is generated by the lowering of the stage (21) wherein the sub-clamp (23b) and the stage(21) are connected to each other by the spring member (25).

### RELATED APPLICATIONS

This application claims priority under 35 U.S.C. § 119 to Japanese Patent Application No. 2018-010248 filed on Jan. 25, 2018, the entire content of which is hereby incorporated by reference.

### BACKGROUND OF THE INVENTION

### 1. Field of the Invention

The present invention relates to a semiconductor manufacturing apparatus which is configured to form a thin film on a surface of a substrate such as a semiconductor wafer, and more particularly, to a structure of a clamp which is configured to fix the substrate to a stage of the semiconductor manufacturing apparatus.

### 2. Description of the Related Art

A sputtering apparatus forms a film by adhesion of sputtering particles traveling from a target to the substrate while holding the periphery of a substrate with a clamp. In this case, the sputtering particles adhere also to an upper surface of the clamp. A thin film adhering to a boundary between the substrate and the clamp causes sticking between the substrate and the clamp, which may hinder removal of the substrate from the clamp after film formation by sputtering. In order to solve this problem, there has been proposed a structure using both a first clamp and a second clamp (see, for example, Japanese Patent Application Laid-open No. 2011-214034 and Japanese Patent Application Laid-open No. 2005-333063).

According to description in the above cited documents, the second clamp is provided so as to be brought into contact with a substrate on an outer side with respect to a contact position of the first clamp against the substrate. According to the disclosure of Japanese Patent Application Laid-open No. 2011-214034, the first clamp and the substrate are separated from each other by the own weight of the second clamp. According to the disclosure of Japanese Patent Application laid-open No. 2005-333063, the first clamp and the substrate are separated from each other by the leverage of the second clamp.

### SUMMARY OF THE INVENTION

When the thickness of the formed thin film increases, the thickness of the thin film deposited at a boundary between the first clamp and the substrate also increases, with the result that it becomes more difficult to separate the first clamp and the substrate from each other. In Japanese Patent Application Laid-open No. 2011-214034, the second clamp that is heavier than the first clamp is provided, and the first clamp and the substrate are separated from each other by the weight of the second clamp. Since the second clamp is smaller than the first clamp in plan view, and materials which can be selected for the clamps are limited, it is difficult to separate the substrate and the first clamp which are sticking together due to the formation of the thick film only by the own weight of the second clamp. Further, it is difficult to separate the substrate and the first clamp which are sticking together due to the formation of the thick film even by the lever provided to the second clamp in Japanese Patent Application laid-open No. 2005-333063.

The present invention has an object to provide a semiconductor manufacturing apparatus including a clamp capable of reliably separating a substrate and a clamp which are sticking together after a deposited film is formed, and a film formation method for a semiconductor device.

To achieve the object, the present invention employs the following measures.

Provided is a semiconductor manufacturing apparatus, including: a stage configured to support a substrate from a back surface of the substrate; a main clamp configured to press a region on an inner side of a front surface outer-peripheral-portion of the substrate; a sub-clamp configured to press a region on an outer side of the front surface outer-peripheral-portion of the substrate; and a spring member configured to couple the sub-clamp and the stage to each other.

Provided is a film formation method for a semiconductor device, including: holding the substrate with a stage configured to support a substrate from a back surface of the substrate, a main clamp configured to press a region on an inner side of a front surface outer-peripheral-portion of the substrate, and a sub-clamp configured to press a region on an inner side of a region on an outer side of the front surface outer-peripheral-portion of the substrate; forming a deposited film on the substrate; lowering the main clamp, the sub-clamp, and the substrate while lowering the stage so that a spring member configured to couple the sub-clamp and the stage expanded; separating the main clamp and the substrate from each other after lowering the main clamp and stopping the main clamp at a first locking portion; and separating the sub-clamp and the substrate from each other after lowering the sub-clamp and stopping the sub-clamp at a second locking portion.

With the use of the above-mentioned measures, the substrate and the clamp which are sticking together due to formation of the deposited film can be easily separated from each other, thereby enabling prevention of a conveyance failure caused by sticking.

### BRIEF DESCRIPTION OF THE DRAWINGS

FIG. 1 is a sectional view for illustrating a schematic configuration of a semiconductor manufacturing apparatus according to an embodiment of the present invention.

FIG. 2A and FIG. 2B are sectional views for illustrating an operation of the semiconductor manufacturing apparatus according to the embodiment of the present invention.

FIG. 3A and FIG. 3B sectional views for illustrating the operation of the semiconductor manufacturing apparatus according to the embodiment of the present invention, which continues from FIGS. 2.

FIG. 4 is an explanatory graph for showing a raising and lowering height of each of a substrate and a stage and a raising and lowering speed of the substrate in the semiconductor manufacturing apparatus according to the embodiment of the present invention.

### DETAILED DESCRIPTION OF THE PREFERRED EMBODIMENTS

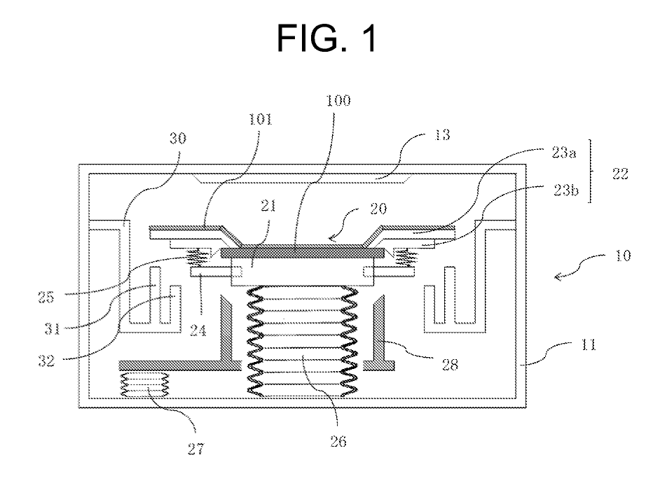

Now, an embodiment of the present invention is described in detail with reference to the drawings. FIG. 1 is a sectional view for illustrating a schematic configuration of a semiconductor manufacturing apparatus according to the embodiment of the present invention. The semiconductor manufacturing apparatus illustrated in FIG. 1 is a sputtering apparatus 10 in which a target 13 and a substrate 100 held by a substrate holder 20 are arranged so as to face each other in a chamber 11 that can be evacuated to a vacuum. Although not shown, supply and discharge mechanism for an inert-gas and an evacuation mechanism for evacuating the chamber 11 are connected to the chamber 11. Further, a conveyance mechanism for the substrate 100 and so on are also provided.

The sputtering apparatus 10 is a film formation apparatus in which an inert gas such as argon collides with the target 13 to eject a material forming the target 13 as sputtering particles and the ejected sputtering particles travel and adhere to a front surface of the substrate 100 to form a deposited film 101. A stage 21 is provided on a back surface of the substrate 100, and the substrate 100 is supported by the stage 21. A vertically movable raising and lowering mechanism 26 for the stage is provided on a back surface of the stage 21 so that the substrate 100 can be sandwiched between the stage 21 and the clamp 22 by raising the stage 21 upward. Further, since the stage 21 does not have a mechanism for fixing the substrate 100, the stage 21 can be easily separated from the substrate 100 by lowering the stage 21.

The clamp 22 includes a main clamp 23a and a sub-clamp 23b. The main clamp 23a and the sub-clamp 23b are formed as follows. The main clamp 23a presses a region on an inner side of the front surface outer-peripheral-portion of the substrate 100. The sub-clamp 23b presses a region on an outer side of the front surface outer-peripheral-portion. The sub-clamp 23b is covered with the main clamp 23a. The region on which the clamp 22 presses the substrate 100 is a region extending from an outer end of the substrate 100 toward the substrate center by a length from 3 mm to 5 mm. A distal end of the main clamp 23a is brought into contact with an inner half of the region, and a distal end of the sub-clamp 23b is brought into contact with the remaining outer half of the region. It is preferred that the main clamp 23a and the sub-clamp 23b are made of a material different from a material which constitutes the target 13, for example, stainless steel. When the target material is not a high-melting-point metal, the clamp 22 may be made of a high-melting-point metal such as titanium or molybdenum.

In FIG. 1, a lower surface of the main clamp 23a and an upper surface of the sub-clamp 23b are shown to have direct contact with each other. However, in consideration of thermal expansion of the clamp material and chronological deformation of the clamp, it is preferred to form some gap between the lower surface of the main clamp 23a and the upper surface of the sub-clamp 23b. Similarly, it is preferred to form a gap also between the distal end portions at which the main clamp 23a and the sub-clamp 23b contact with the substrate 100.

One end of a coil-shaped spring member 25 is connected to a back surface of the sub-clamp 23b, and the other end of the spring member 25 is connected to a spring connecting portion 24 protruding from a side surface of the stage 21. In general, as the coil-shaped spring, there are given a compression coil spring and a tension coil spring. Herein, the tension coil spring that is used to receive a tensile load is employed. It is desired that the spring members 25 are arranged at equal intervals on the periphery of the stage 21 and are provided at least at three positions. During film formation, the sputtering particles adhere not only to the substrate 100 but also to the front surface and the periphery of the main clamp 23a to form the deposited film 101. For easy removal of the deposited film 101 in the chamber 11, an adhesion preventing plate 30 is provided in the periphery of the stage 21. The adhesion preventing plate 30 in the embodiment of the present invention includes the first locking portion 31 and the second locking portion 32 provided in an inner side of the first locking portion 31. The first locking portion 31 is formed so that an upper end thereof can contact the back surface end portion of the main clamp 23a. The second locking portion 32 is formed so that an upper end thereof can contact the back surface end portion of the sub-clamp 23b. The first locking portion 31 and the second locking portion 32 are provided so that the height of the upper end of the second locking portion 32 is lower than the height of the upper end of the first locking portion 31. Further, a substrate locking portion 28 for the substrate 100 is provided in a further inner side of the second locking portion 32, that is, at a position closer to the stage 21 than the second locking portion 32. The substrate locking portion 28 includes a vertically movable raising and lowering mechanism 27 for the substrate locking portion, and an upper end of the substrate locking portion 28 is formed so as to contact with the back surface end portion of the substrate 100.

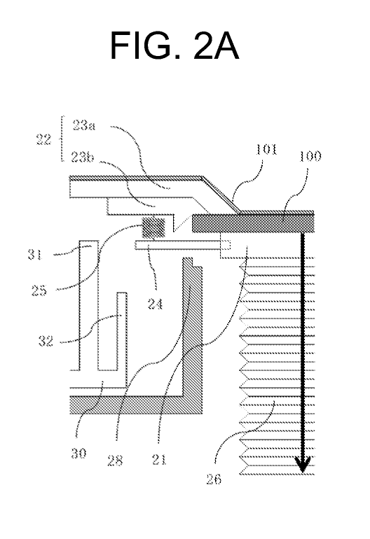

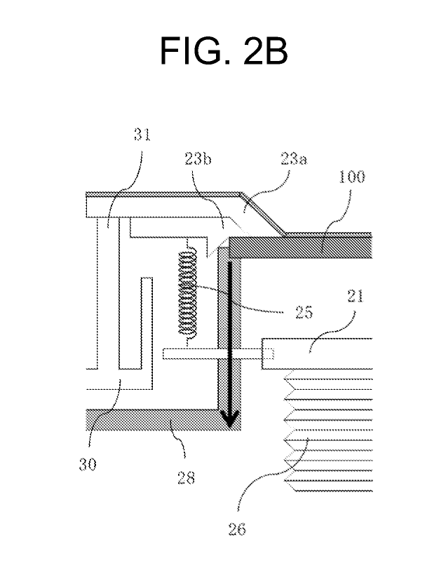

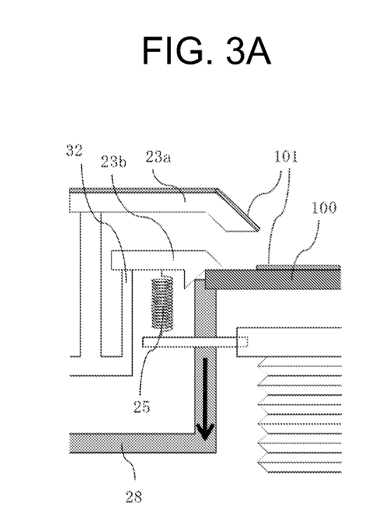

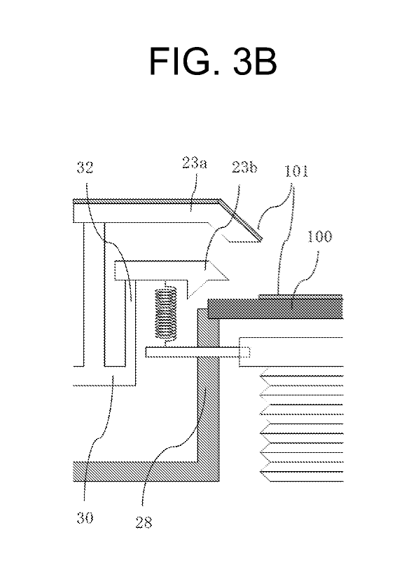

FIGS. 2A to 3B are sectional views for illustrating an operation of the semiconductor manufacturing apparatus according to the embodiment of the present invention. Now, a film formation method for a semiconductor device is described with the semiconductor manufacturing apparatus according to the embodiment of the present invention.

In FIG. 2A, illustration is given of a condition in which the stage 21 is raised so that the substrate 100 on which a semiconductor device is later formed is sandwiched between the stage 21 and the clamp 22. The distal end portion of the main clamp 23a contacts with a region on an inner side of the front surface outer-peripheral-portion of the substrate 100, and the distal end portion of the sub-clamp 23b contacts with a region on an outer side of the front surface outer-peripheral-portion, with the result that the substrate 100 is pressed downward. In this case, the spring member 25 provided between the sub-clamp 23b and the spring connecting portion 24 is contracted to be shorter than the spring free length. Further, the height of the substrate 100 in this case is higher than the upper end of the first locking portion 31, and the upper end of the first locking portion 31 and a back surface of the main clamp 23a do not contact with each other. In this condition, the deposited film 101 is formed on the front surface of the substrate 100. The formed deposited film 101 continuously covers the substrate 100 and the main clamp 23a.

As illustrated in FIG. 2B, the substrate locking portion 28 is raised to bring an upper portion thereof into contact with the back surface end portion of the substrate 100. The substrate locking portion 28 is required for alleviation of impact on the substrate 100 in the subsequent steps. Next, the stage 21 is lowered by the raising and lowering mechanism 26 for the stage so that the spring member 25 is expanded to be longer than the spring free length. Then, a force for contracting the spring member 25 is generated, and the main clamp 23a and the sub-clamp 23b are lowered while keeping contact with the substrate 100. The lowering speed in this case is controlled by the raising and lowering mechanism 27 for the substrate locking portion. Suppose that there is no substrate locking portion 28 having the raising and lowering mechanism 27 for the substrate locking portion, the lowering speed of the substrate 100 is determined by the contraction force of the spring member 25, and hence it is difficult to control the lowering speed. When the upper end of the first locking portion 31 contacts with the back surface end portion of the main clamp 23a, the lowering of the main clamp 23a stops. The lowering speed may be a constant, but the impact on the substrate 100 can be alleviated by decreasing the lowering speed immediately before the first locking portion 31 and the main clamp 23a contacts with each other.

When the substrate locking portion 28 is further lowered, the deposited film 101 deposited at the distal end of the main clamp 23a is disconnected, and the substrate 100 and the main clamp 23a are separated from each other. During separation, in order to suppress peeling and rolling up of an end portion of the deposited film 101 on the surface of the substrate 100, it is preferred that the lowering speed immediately after the contact between the first locking portion 31 and the main clamp 23a is further decreased. When the main clamp 23a and the substrate 100 are separated from each other, as illustrated in FIG. 3A, the sub-clamp 23b is further lowered while keeping contact with the substrate 100. When the upper end of the second locking portion 32 contacts with the back surface end portion of the sub-clamp 23b, the lowering of the sub-clamp 23b stops. The lowering speed may be a constant, but the impact on the substrate 100 can be alleviated by decreasing the lowering speed immediately before the second locking portion 32 and the sub-clamp 23b contact with each other.

Next, as illustrated in FIG. 3B, when the substrate locking portion 28 is further lowered, the substrate 100 and the sub-clamp 23b are separated from each other. There is no continuous deposited film on the distal end portion of the sub-clamp 23b and the front surface outer-peripheral-portion of the substrate 100, and hence the substrate 100 and the sub-clamp 23b can be easily separated from each other. In this case, the substrate 100 is placed on the substrate locking portion 28 while the back surface of the substrate 100 is not supported by the stage 21, and the clamp 22 does not contact with the front surface of the substrate 100.

Next, the substrate 100 is unloaded from a position above the stage 21 through use of the conveyance mechanism such as a robot arm (not shown), and then is accommodated in a carrier. The next substrate 100 subjected to film formation is taken out from the carrier and placed on the stage 21, and the front surface outer-peripheral-portion thereof is pressed by the clamp 22. Then the above-mentioned steps are repeated, and film formation on a semiconductor device is performed.

As described above, in the sputtering apparatus 10 of the present invention, through the action of the contraction force of the spring provided between the stage 21 and the sub-clamp 23b, even when sticking occurs between the clamp 22 and the substrate 100 through intermediation of the deposited film 101, the clamp 22 and the substrate 100 can be reliably separated from each other, and a conveyance failure of the substrate 100 caused by sticking can be prevented.

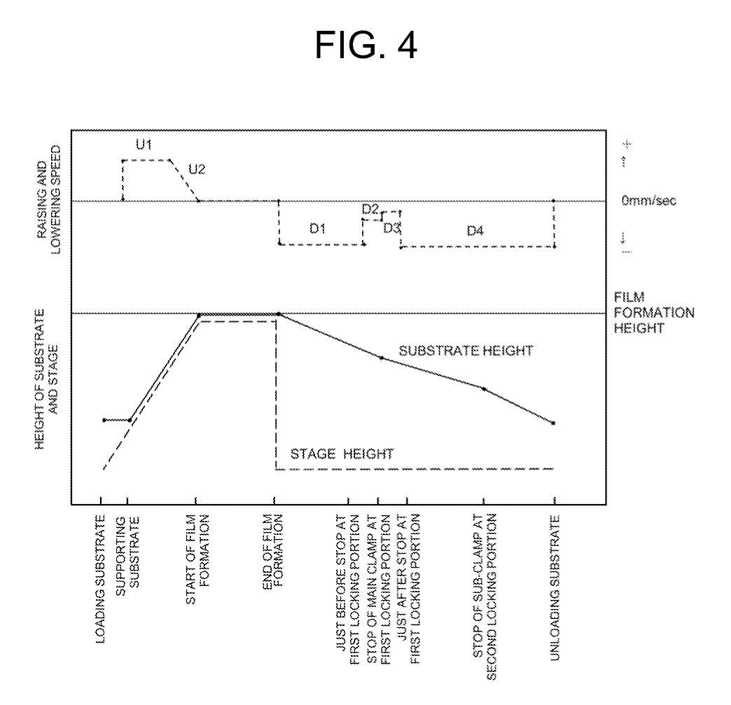

FIG. 4 is an explanatory graph for showing a raising and lowering height of each of the substrate and the stage and a raising and lowering speed of the substrate in the semiconductor manufacturing apparatus according to the embodiment of the present invention. In FIG. 4, the horizontal axis shows steps from loading of the substrate to unloading of the substrate, and the vertical axis shows the raising and lowering speed of the substrate and the heights of the substrate and the stage. In the following, for thorough understanding, description is made also with reference to FIGS. 2A to 3B.

### Loading of Substrate to Start of Formation of Deposited Film (See FIG. 3B)

The substrate 100 is placed on the substrate locking portion 28 that locates at a position a little higher than the stage 21 so as to be separated from the stage 21, and the stage 21 is raised at the first raising speed U1. When the upper surface of the stage 21 is brought into contact with the back surface of the substrate 100, the stage 21 is raised with the substrate 100 placed thereon. Next, the substrate 100 is raised at the second raising speed U2 which gradually decreases from the first raising speed U1 to 0 mm/sec.

### Start of Formation of Deposited Film to End of Formation of Deposited Film (See FIG. 2A)

When the substrate 100 reaches the film formation height, the raising of the substrate 100 is stopped. Then, the argon gas is introduced into the chamber 11, and is discharged, to thereby cause activated argon atoms to collide to the target 13. Thus, sputtering particles ejected from the target 13 travel to the substrate 100 to form a film on the substrate 100. In these steps, substrate 100 is in a stationary state, and the substrate raising and lowering speed is 0 mm/sec.

End of Formation of Deposited Film to Immediately after Stop with First Locking Portion (See FIG. 2B)

The substrate locking portion 28 is raised to be brought into contact with the back surface end portion of the substrate 100. Then, the stage 21 is lowered to the lowest position which is the same as the position during loading of the substrate 100 so that the spring member 25 is expanded. Next, the substrate 100 held by the substrate locking portion 28 is lowered at a first lowering speed D1. When the main clamp 23a is brought close to the vicinity of the first locking portion 31, the first lowering speed D1 is decreased to a second lowering speed D2, and the first locking portion 31 and the main clamp 23a are brought into contact with each other. At this time, the main clamp 23a and the substrate 100 stick to each other through intermediation of the deposited film 101. When the substrate 100 is lowered at high speed, the impact applied at a time of the contact between the first locking portion 31 and the main clamp 23a thus propagates to the substrate 100 through the main clamp 23a. However, the impact propagated to the substrate 100 can be alleviated by decreasing the lowering speed as described above. When the first locking portion 31 and the main clamp 23a are brought into contact with each other, the second lowering speed D2 is further decreased to a third lowering speed D3, and the main clamp 23a and the substrate 100 are separated from each other. Such action is performed in order to suppress peeling and rolling up of the end portion of the deposited film 101 on the surface of the substrate 100 during separation. When the deposited film 101 is made of a high-melting-point metal film, an internal stress is high, and film peeling may be originated from a damage of the end portion of the deposited film 101. Thus, the decrease in speed is an effective measure for avoiding such problem.

Immediately after Stop with First Locking Portion to Stop of Sub-Clamp with Second Locking Portion (See FIG. 3A)

When the main clamp 23a and the substrate 100 are separated from each other, the lowering speed is increased to a fourth lowering speed D4, and the substrate 100 and the sub-clamp 23b are lowered while keeping contact with each other. When the sub-clamp 23b is brought into contact with the second locking portion 32, the sub-clamp 23b is separated from the substrate 100, and the lowering operation of the sub-clamp 23b is stopped.

Stop of Sub-Clamp with Second Locking Portion to Unloading of Substrate (See FIG. 3B)

Only the substrate 100 held by the substrate locking portion 28 is lowered at the fourth lowering speed D4, and the lowering of the substrate 100 is stopped with a gap being formed between the sub-clamp 23b and the substrate 100. In this case, the substrate 100 and the stage 21 below the substrate 100 are also separated from each other with a gap being formed therebetween. Next, the substrate 100 having the deposited film 101 formed thereon is unloaded through use of a conveyance apparatus. The gaps above and below the substrate 100 are required as movable regions for a conveyance arm of the conveyance apparatus and the substrate 100.

The impact on the substrate 100 can be avoided and a conveyance failure of the substrate 100 caused by sticking can be prevented through regulation of the lowering speed of the substrate 100 in the above-mentioned film formation method.

What is claimed is:

1. A semiconductor manufacturing apparatus, comprising:
a stage configured to support a substrate from a back surface of the substrate;
a main clamp configured to contact with an inner side of a pressing region in a front surface outer-peripheral-portion of the substrate;
a sub-clamp configured to contact with an outer side of the pressing region; and
a spring member configured to couple the sub-clamp and the stage to each other.

2. A semiconductor manufacturing apparatus according to claim 1, further comprising:
a first locking portion provided under the main clamp;
a second locking portion provided under the sub-clamp, and is lower than the first locking portion; and
a substrate locking portion provided under the substrate.

3. A semiconductor manufacturing apparatus according to claim 1, wherein the spring member comprises a tension coil spring.

4. A semiconductor manufacturing apparatus according to claim 2, wherein the spring member comprises a tension coil spring.

5. A film formation method for a semiconductor device, comprising:
holding the substrate with a stage configured to support a substrate from a back surface of the substrate, a main clamp configured to contact with an inner side of a pressing region in a front surface outer-peripheral-portion of the substrate, and a sub-clamp configured to contact with an outer side of the pressing region;
forming a deposited film on the substrate;
lowering the main clamp, the sub-clamp, and the substrate while lowering the stage so that a spring member configured to couple the sub-clamp and the stage to each other is expanded;
separating the main clamp and the substrate from each other after lowering the main clamp and stopping the main clamp with a first locking portion; and
separating the sub-clamp and the substrate from each other after lowering the sub-clamp and stopping the sub-clamp with a second locking portion.

6. A film formation method for a semiconductor device according to claim 5, further comprising supporting the substrate with a substrate locking portion before lowering the main clamp, the sub-clamp, and the substrate.

7. A film formation method for a semiconductor device according to claim 6, further comprising decreasing a lowering speed in separating the main clamp and the substrate from each other as compared to a lowering speed in lowering the main clamp, the sub-clamp, and the substrate.
